(19) United States
(12) Patent Application Publication
(10) Pub. No.: US 2014/0102745 A1
(43) Pub. Date: Apr. 17, 2014

(54) Electrical Screw Extender

(71) Applicant: Alejandro A. Gomez, Miami, FL (US)

(72) Inventor: Alejandro A. Gomez, Miami, FL (US)

(21) Appl. No.: 14/053,518

(22) Filed: Oct. 14, 2013

Related U.S. Application Data
(60) Provisional application No. 61/713,824, filed on Oct. 15, 2012.

(51) Int. Cl. H05K 5/02; F16B 33/00; F16B 39/00

(52) U.S. Cl. CPC H05K 5/0217; F16B 39/00; F16B 33/002
USPC 174/50; 411/222

(57) ABSTRACT

The objective of the present invention is to provide electrical boxes, electrical mud rings and electrical box extenders with a cheap and efficient way to achieve the correct location of electrical devices with respect to the levels of the walls where they are located. With this electrical screw extender, a mechanical/electrical connection is still safe and lasting too. This electrical screw extender has among its advantages that can be placed in different models of electrical boxes and in mud rings, plus it can be used independently in the already existing constructions to extend the points of connection of devices to the correct levels. Besides, these electrical screw extenders can have different sizes or lengths to suit the different depths of the existing electrical boxes or mud rings, as well as are very comfortable and accurate in their use.

### CROSS-REFERENCE TO RELATED APPLICATIONS

This application claims the benefit of PPA No. 61/713,824, filed Oct. 15, 2012 by the present inventor. EFS ID 13984828

### FEDERALLY SPONSORED RESEARCH

None

### SEQUENCE LISTING

None

### BACKGROUND OF THE INVENTION

This invention relates to an adjustable electrical box screw extender which may be attached to a conventional electrical junction box, a mud ring or can be used alone to enable positioning on the place, where the fixing screws of the electrical devices are inserted, at selectable distances from the junction box or mud ring.

Because of various state and federal codes, the wiring of a building today requires the use of metal conduits for holding electrical wires, and so-called electrical junction boxes on which may be mounted a variety of electrical switches or plugs for access by the users of the building. Such conduits and junction boxes are mounted within the walls of the building, with openings provided in the walls for access to the junction boxes. These junction boxes are closed on all sides except where joined to conduits and except for the fronts of the boxes which face the openings in the walls.

It is desirable that the open front of a junction box or the insertion point for the fixing screws of the electrical devices be positioned adjacent to the surface of the wall so that when a switch or plug is mounted in the junction box, the front of the switch or plug will be substantially flush with the surface of the wall. However, because of the wide variety of types of walls in which the conduit and electrical junction boxes are installed, and because the junction boxes are typically installed before the wall surfaces are applied to studs or the like, it is difficult to estimate the proper location of the junction box to ensure that the front of the switch or plug will be flush with the wall surface. If the junction box protrudes out from the wall surface, then the switch or plug will appear unsightly, whereas if the junction box is recessed too far from the wall surface, then the switch or plug to be mounted therein may not be adequately protected from spark or other electrical hazards reaching surrounding combustible materials. Also, if the junction box is too far recessed from the wall surface, it may not even be possible to mount the switch or plug therein.

A number of adjustable electrical outlet boxes have been proposed to allow mounting a switch or plug so that it is substantially flush with a wall surface. Among these are those disclosed in U.S. Pat. Nos. 1,875,101; 2,048,611; 3,433,886; 4,634,015; 5,098,046; 5,114,105; 5,253,831; 5,289,934; 5,931,325; 6,369,322; 7,002,076; 7,462,775 and 8,245,862. These arrangements all show a combination of a specialized junction box and a slid able element for holding a switch or plug and as such require installation of the specialized junction box everywhere the device is to be used. That is, the device cannot be used with conventional junction boxes and so if the device is going to be used it must be installed at the beginning. This may result in an unnecessary expense since a conventional junction box might have been just as suitable, but such determination is often difficult before the building is constructed.

### SUMMARY OF THE INVENTION

The object of the present invention is to provide an adjustable electrical screw extender attachment which may be mounted on a conventional electrical junction box, mud ring or to be used alone and in which may be installed a conventional electrical switch, outlet or any kind of electrical or communication devices.

It is another object of the invention to provide such electrical screw extender which may be installed after a building wall or other supporting structure is constructed.

It is another object of the invention to provide electrical box, electrical mud ring and electrical box extender with a system incorporated to accept the assembly of the electrical screw extender.

It is an additional object of the invention to provide such electrical screw extender in which intimate electrical and mechanical contact is maintained between an installed electrical device and the conventional junction box or mud ring.

It is a further object of the present invention to provide such electrical screw extender wherein the disposition of the outlet or switch relative to the junction box may be manually adjusted so that the front edge of said outlet or switch can be positioned substantially flush with a wall surface in which said outlet or switch is installed.

It is a further object of the present invention to provide electrical junction box, electrical mud ring and electrical box extender with an incorporated system to accept the easy assembly of the electrical screw extender.

It is also an object of the invention to provide such electrical screw extender wherein no fasteners or other implements project into the installed junction box.

It is also an object of the invention to use only standard bolts sizes, readily available bolts sizes which enable the installer to make use of them.

It is also an object of the invention to simplify the way of manufacturing and the use of the invention.

### BRIEF DESCRIPTION OF THE DRAWINGS

The above and other objects, features and advantages of the invention will become apparent from a consideration of the following detailed description presented in connection with the accompanying drawings in which:

FIG. 1 is a perspective view of all the system, including the electrical box, the mud ring, the electrical screw extender and the electrical box extender.

FIG. 2 is a perspective view of an electrical screw extender and how the fixed portion of said electrical screw extender is placed inside a 2 gang electrical box.

FIG. 3 is a perspective view of an electrical screw extender and how the fixed portion of said electrical screw extender is placed inside a 2 gang mud ring.

FIG. 4 is a perspective view of a 2 gang electrical box extender with a circular plastic duct to mount said electrical box extender at the electrical screw extender.

FIG. 5 is a perspective view of an electrical screw extender and its fixed base.

FIG. 6 is a lateral view of an electrical screw extender and its fixed base.

FIG. 7 is a perspective view of an electrical screw extender used with a regular switch.

FIG. 8 is a top perspective view of a 2 gang electrical box extender.

FIG. 9 is a front view of a 2 gang electrical box extender.

FIG. 10 is a perspective view of an electrical screw extender and a regular screw of the electrical devices.

### DETAILED DESCRIPTION

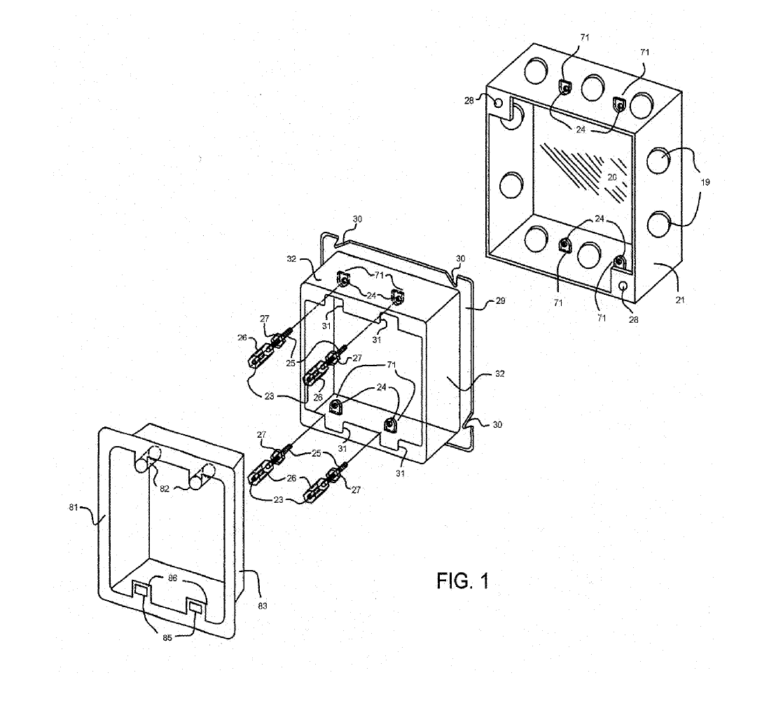

FIG. 1 is a perspective view which also shows the system that can be used with the electrical screw extender. First is a 2 gang electrical box 21 with its different knockouts 19, two treated internally threaded holes 28 and the fixed bases 71 with the internal thread 24 and the covered back 20. Next we see a mud ring 32 with its flat base 29 and location slots 30. For guiding hexagonal part 26 of the electrical screw extender, it is desirable that the upper and lower edges of said mud ring 32 must have four displacement openings 31 which enable with a nut driver. Next we see four electrical screw extenders with the external thread 25 and the internal thread 23, the hexagonal part 26 and the regulation nut 27. And last we see the two gang electrical box extender 83 with two ducts 82; two tabs 86 with two slots 85 and the border 81.

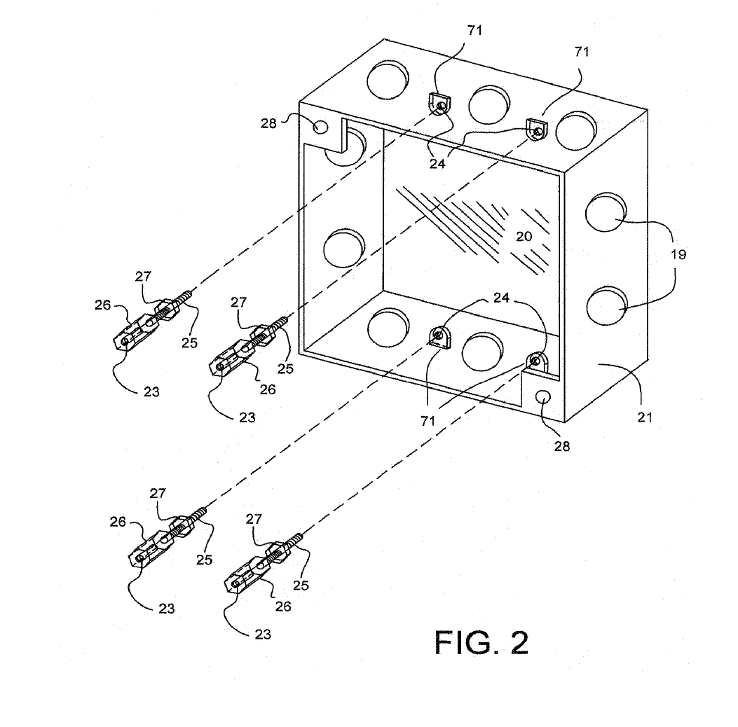

FIG. 2 is a perspective view which shows the electrical screw extender used in electrical box 21 with its different knockouts 19 with two internally threaded holes 28 and the covered back 20. The various component parts of the electrical screw extender and its fixed base 71 are shown where said fixed base 71 is inside and fixed to said electrical box 21. Said fixed bases 71 are observed with their respective internal threads 24 into which external threads or male screws 25 from electrical screw extender may be located to vary the distance from the final position. In the part of said external thread or male screw 25 of said electrical screw extender, locknuts 27 are observed, which serve as a means of fixing the selected distances. The hexagonal portion 26 of the electrical screw extenders must have a regular size, can be guided with a nut driver and also has at its center a treated internal thread 23 where the screws of any standard electrical devices can be placed. The sizes of these internal threads 23 are the standard 6/32 in the case of USA but they could be of another size in order to standardize the measures to those of regular use in other countries. For convenience so that the electrical screw extender can be used directly on the threads of the devices that mud rings have, external threads or male screws 25 of said electrical screw extender and female screws or internal threads 23 which are in the hexagonal part of this electrical screw extender must be both the same measure and standardized to the countries where they are used. By extension the inner threaded portion 24 which is located on the fixed base 71 also must be of the same measure as 6/32 is in the case of USA.

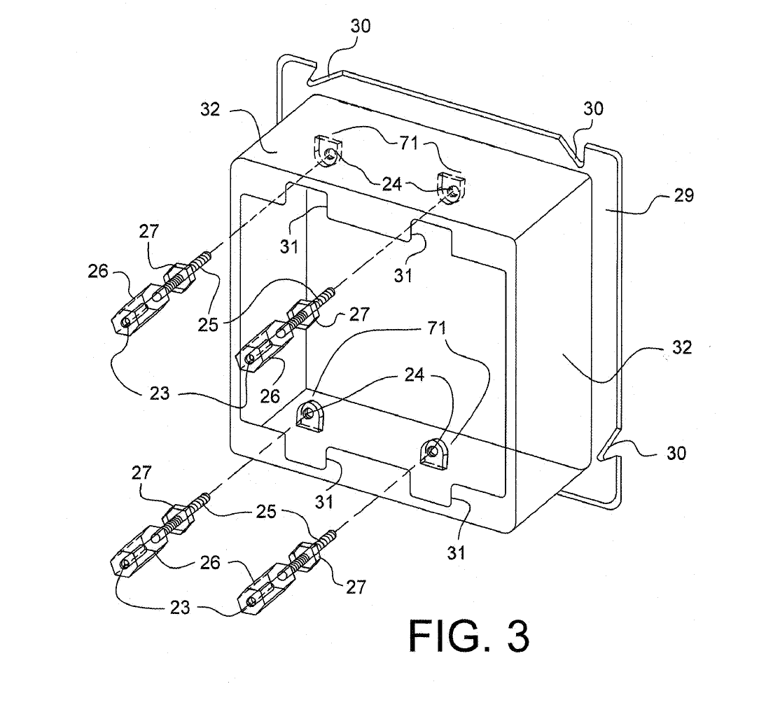

FIG. 3 is a perspective view showing a regular mud ring 32 with its flat base 29 and location slots 30. The internal threads 24 which are on said bases 71 should be spaced such that the separation from that it is located in the upper edge and that it is located in the lower edge is the same as the separation that exists among fixing screws in electrical devices like outlets or switches. Like it happens to the electrical boxes, It is also recommended that in the initial location, the outer edge of hexagonal portion 26 of said electrical screw extender and its internal thread 23 are completely flush with the outer edge of the mud ring 32, whether all portion of the outer thread or male screw 25 of said electrical screw extender is fully inside the inner thread 24 of the fixed base 22 including the width of the locknut 27. For guiding hexagonal part 26 of this electrical screw extender, it is desirable that the upper and lower edges of the mud ring 32 have four displacement openings 31 which enable with a nut driver, the proper and flush placement with the walls of said different hexagonal parts 26 of electrical screw extenders.

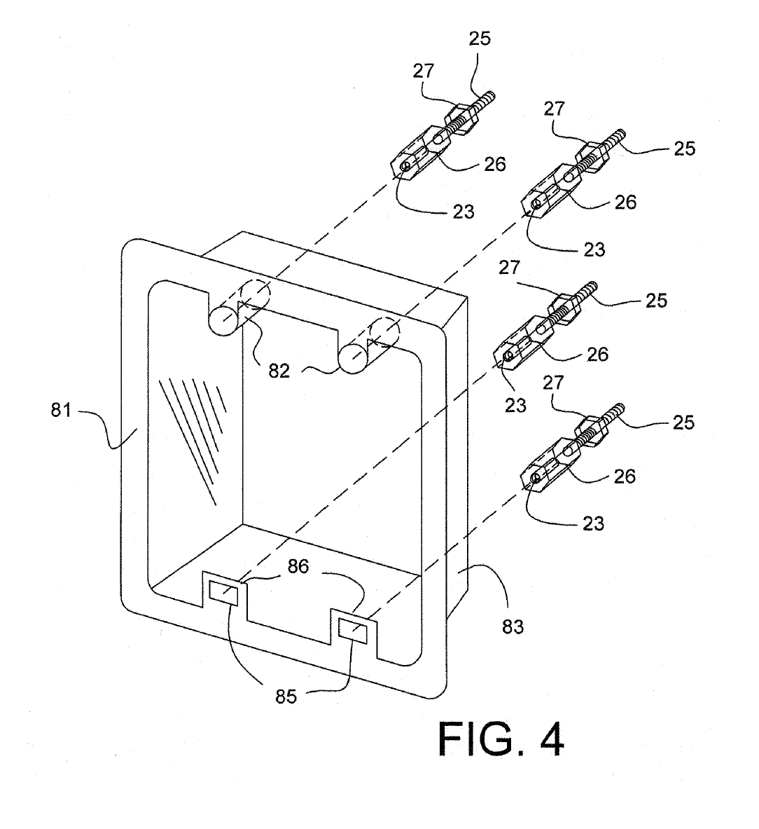

FIG. 4 is a perspective view showing a two gang electrical box extender 83 which has two ducts 82 to mount said electrical box extender 83 in the hexagonal part 26 of the electrical screw extender. The tab 86 has a slot 85 to insert the device's screws in the female thread 23 of the electrical screw extender. Border 81 does not have to be wide because this box extender 83 is not supported by walls.

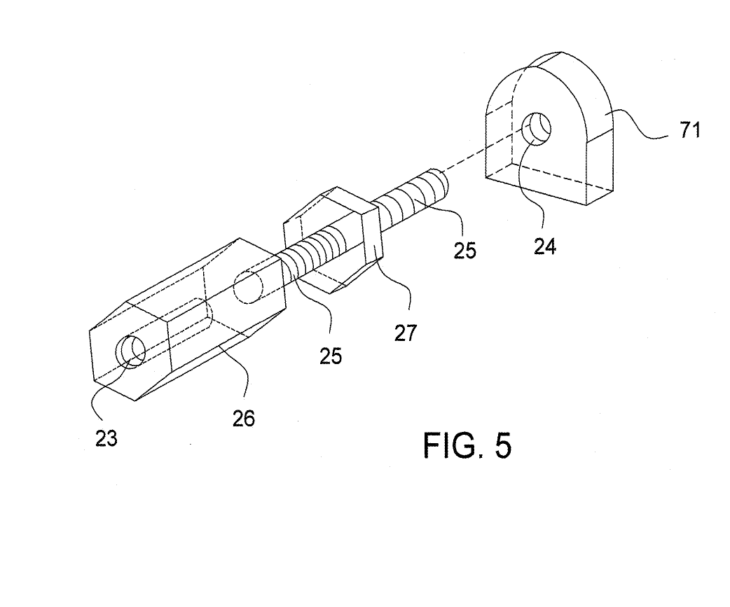

FIG. 5 is a perspective view showing the electrical screw extender with all of its parts and the fixed base 71 with its internal thread 24 which is capable of accepting the full length of male external thread 25 of said electrical screw extender. The lower parts of the fixed base 71 must be flat for easy fastening of said fixed part 71 in the electrical box 21 or mud ring 32. The locknut 27 can be displaced along the length of the outer or male thread 25 of the electrical screw extender. The hexagonal part of the electrical screw extender 26 and its internal thread 23 is capable of accepting the screws of electrical devices like outlets or switches that can be sized smaller than the screw of said electrical device in which case a cut of the length of the fixing screw of electrical devices must be made or it must be replaced by a smaller one or even the electric screw extender manufacturer could provide an appropriately sized screw for the electrical devices. Said hexagonal part 26 can be too circular or any other geometric shape with some slot to be guided with a screwdriver. As previously stated, the length of said electrical screw extender and its hexagonal part can be variable depending on the width of the electrical box or mud ring where they are located. Also if these electrical screw extenders are to be used in existing buildings to provide the appropriate location of electrical devices, they may have different sizes so that they help us measure walls or work circumstances where they can be used.

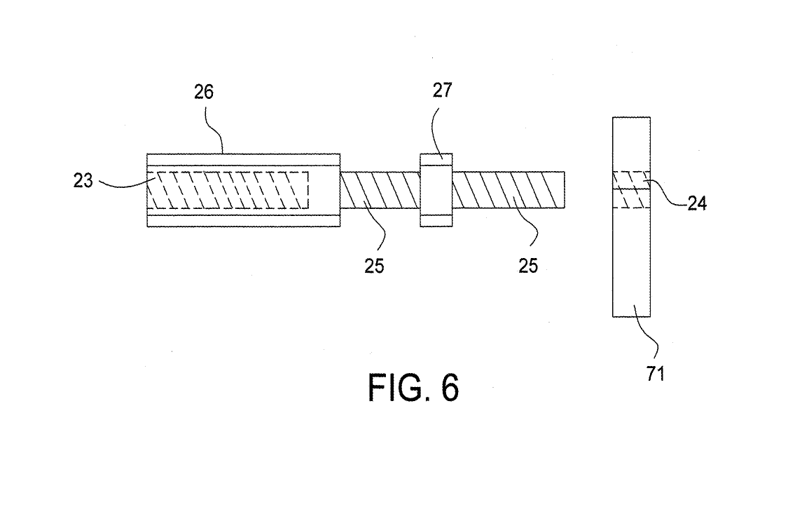

FIG. 6 shows a lateral view of the electrical screw extender with its fixed base 71 where the internal thread 24 is located which can accept the outer or male thread 25 of the electrical screw extender. The lock nut 27 is movable over said male or external thread 25 and the hexagonal part 26 has an internal thread 23 which can accept screws from electrical devices. Said hexagonal part 26 can be circular, octagonal or any other geometric shape with some slot to be guided by a screwdriver.

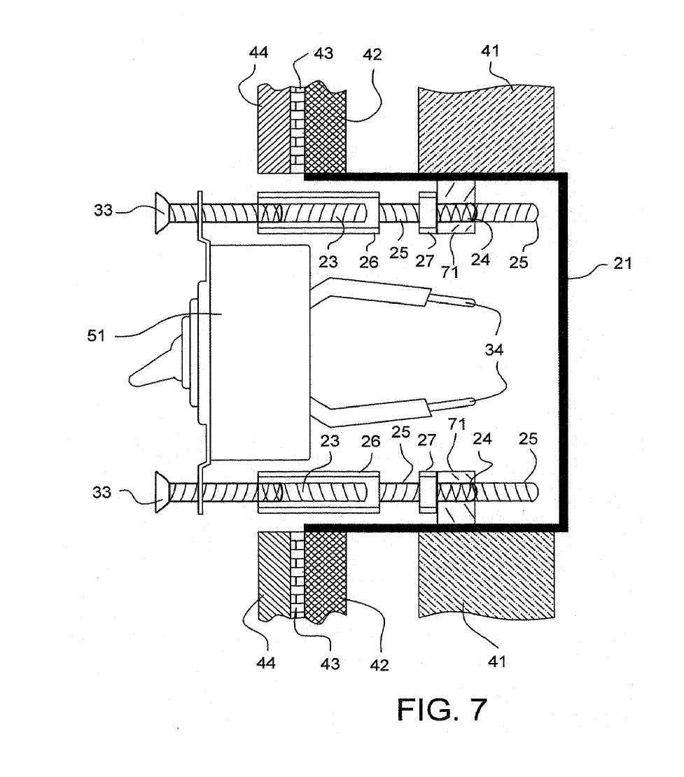

FIG. 7 shows a side view where an electrical switch 51 can be located properly flush with a new wall of tiles 44 that was located with the adhesive 43 on the sheet rock wall 42. As usual, the electrical box 21 is fixed on one side in the wood beam 41 and the device mounting bolts 33 are placed into the internal thread 23 of the hexagonal part 26 of the electrical screw extender. The fastening nut 27 is tightened against the fixed base 71 after the portion of the outer or male thread 25 of the electrical screw extender has reached the correct distance in its displacement within the inner thread 24 of said flat base 71. As an extra safety measure to avoid a possible displacement of the external or male thread 25 of the electrical screw extender on the thread of the locknut 27 and the internal thread 24 of the flat base 71, said outer or male thread 25 may be damaged by any tool at the exact point that coincides with the outer edge of said security thread 27. The cables 34 are those normally connected to any electrical switch.

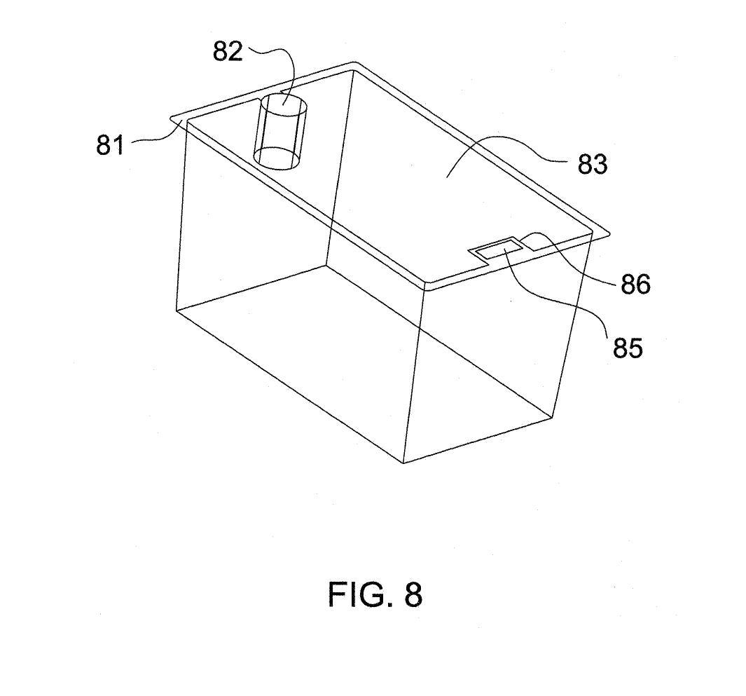

FIG. 8 is a top perspective view for an electrical box extender 83 with one gang showing the duct 82, the border 81 the tab 86 with the slot 85.

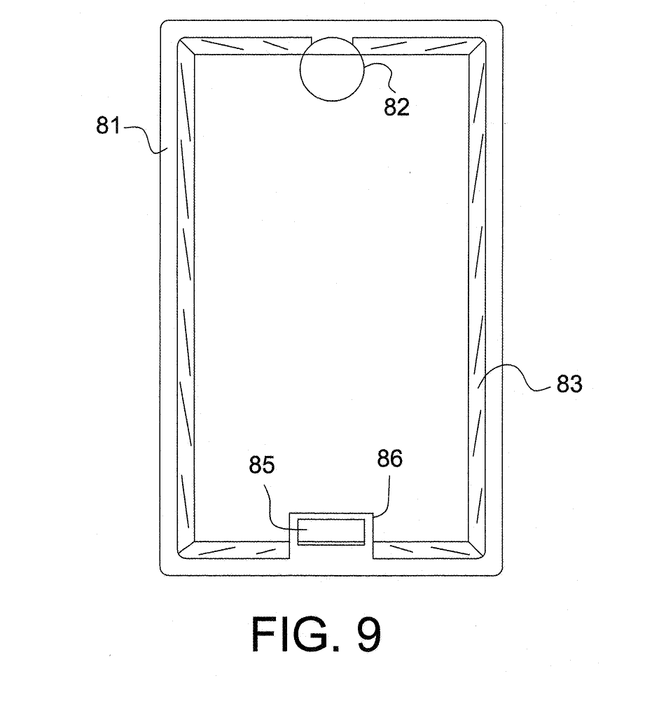

FIG. 9 is a frontal view of the same one gang electrical box extender 83 shown in FIG. 8 with the same parts like duct 82, border 81, tab 86 and the slot 86.

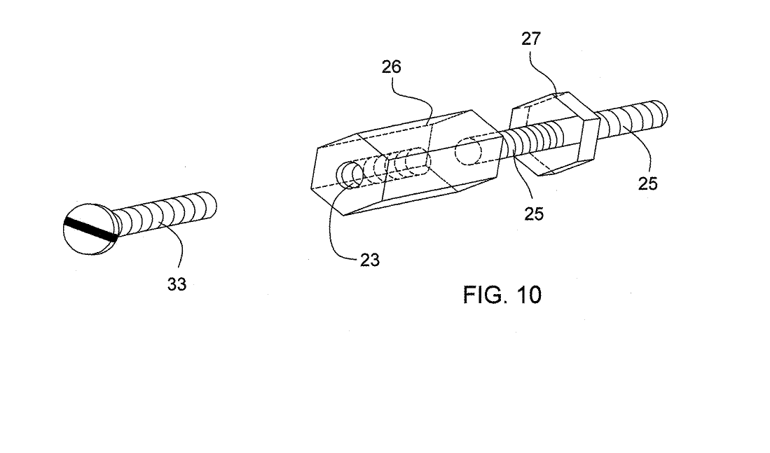

FIG. 10 is a perspective view showing the electrical screw extender and its different parts, such as the external or male thread 25, the lock nut 27, and the exterior hexagonal part 26 with which the exact location of the electrical screw extender is achieved using a nut driver and the internal thread 23 of said hexagonal part 26, which is able to accept the screws from electrical devices 33. As a reminder, in the U.S., thread sizes are 6/32 for screws of electrical devices 33, too for the male or external thread 25 of the electrical screw extender, for the inner thread 23 of the hexagonal portion 26 of said electrical screw extender and the internal thread 24 of the fixed base 72, but this measure may be another if we use these electrical screw extenders in other countries.

It is to be understood that the above-described arrangements are only illustrative of the application of the principles of the present invention. Numerous modifications and alternative arrangements may be devised by those skilled in the art without departing from the spirit and scope of the present invention and, the appended claims are intended to cover such modifications and arrangements.

I claim:

1. An electrical screw extender capable of maintaining a mechanical and electrical continuity between the electrical devices and the mud ring or electrical box and at the same time, serves to change the point of fixation of said electrical devices, wherein said electrical screw extender compress:
a. An internally threaded part capable to accept screws of different electrical devices.
b. An externally threaded portion or male capable of being inserted in the threads of the mud rings or inserting points of electrical devices located in any electrical box or in the internal thread of the fixed portion which is mounted in said electrical boxes or said mud rings.
c. A lock nut which can be moved down the length of the external threaded portion or male screw of said electrical screw extender that is to set the correct distance from the location of said electrical screw extender.
d. A wider exterior part to guide said electrical screw extender wherein said exterior part can be hexagonal.
e. A fixed based with internal thread capable of accepting all exterior thread of the electrical screw extender wherein said fixed base is mounted, separate from the external border, in the junction box or mud ring.

2. An electrical mud ring with openings able to accept a nut driver or screwdriver to handle the wider exterior part of the electrical screw extender and with fixed bases separate from the external border, wherein said fixed parts are capable of accepting the external threads or male screws of said electrical screw extender.

3. The electrical box extender with a duct to mount said electrical box extender in the wider exterior part of the electrical screw extender.
